(19) United States
(12) Patent Application Publication
(10) Pub. No.: US 2008/0316607 A1
(43) Pub. Date: Dec. 25, 2008

(54) IMAGE SENSOR AND METHOD OF MANUFACTURING THE SAME

(75) Inventor: Jin Ho PARK, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/145,443

(22) Filed: Jun. 24, 2008

(30) Foreign Application Priority Data
Jun. 25, 2007 (KR) 10-2007-0062023

(51) Int. Cl. G02B 7/00; H01L 21/00

(52) U.S. Cl. 359/642; 438/70

(57) ABSTRACT

An image sensor and a method of manufacturing the same. In one example embodiment, an image sensor includes an interlayer insulation layer formed on a substrate of a pixel area, a plurality of first microlenses spaced apart from each other on the interlayer insulation layer, and a plurality of second microlenses formed beside the plurality of first microlenses. The plurality of second microlenses each has a diameter different from a diameter of each of the plurality of first microlenses.

### CROSS-REFERENCE TO A RELATED APPLICATION

This application claims the benefit of Korean Patent Application No. 10-2007-0062023, filed on Jun. 25, 2007 which is hereby incorporated by reference as if fully set forth herein.

### BACKGROUND

1. Field of the Invention

The present invention relates to a semiconductor device, and more particularly to an image sensor and a method of manufacturing the same.

2. Description of the Related Art

In general, an image sensor is a semiconductor device capable of converting an optical image into an electric signal. Two types of image sensors are charge coupled devices (CCDs) or complementary metal oxide silicon (CMOS) image sensors (CISs). A CIS sequentially detects electrical signals of respective unit pixels to obtain an image in a switching scheme by adapting a photodiode and a MOS transistor within each unit pixel.

In order to increase the light sensitivity of an image sensor, the image sensor may occupy a relatively large area of a photodiode, or the image sensor may employ focusing technology capable of focusing light on the image sensor that is incident upon an area beside the image sensor. One type of focusing technology is a microlens.

Microlenses are typically formed on image sensors using a micro photo process that employs a special photoresist for a microlens and then employs a reflow scheme. However, using typical manufacturing processes, a relatively high amount of photoresist is lost during the reflow of photoresist, which sometimes results in a gap between microlenses. The gap between microlenses results in a reduction in the amount of light detected by the photodiode, which can result in image defects. In addition, the gap between microlenses causes a decrease in the fill-factor of the microlenses. Furthermore, light can enter through the gap between microlenses, resulting in crosstalk between pixels. The gap between also results in an overall decrease in light sensitivity of the corresponding image sensors.

### SUMMARY OF EXAMPLE EMBODIMENTS

In general, example embodiments of the invention relate to an image sensor and a method of manufacturing the same which is capable of reducing or eliminating a gap between microlenses, thereby increasing the sensitivity of the image sensor.

In one example embodiment, an image sensor includes an interlayer insulation layer formed on a substrate of a pixel area, a plurality of first microlenses spaced apart from each other on the interlayer insulation layer, and a plurality of second microlenses formed beside the plurality of first microlenses. The plurality of second microlenses each has a diameter different from a diameter of each of the plurality of first microlenses.

In another example embodiment, a method of manufacturing an image sensor includes forming an interlayer insulation layer on a substrate of a pixel area, forming a plurality of first microlenses spaced apart from each other on the interlayer insulation layer, and forming a plurality of second microlens beside the pluralities of first microlenses. In this example embodiment, the plurality of second microlenses are each formed to have a diameter different from a diameter of each of the plurality of first microlenses.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of example embodiments of the invention and are incorporated in and constitute a part of this application, illustrate example embodiments of the invention. In the drawings:

FIGS. 1 to 4 illustrate an example manufacturing processes of an example image sensor.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

Hereinafter, an example image sensor and a method of manufacturing the same will be described in detail with reference to the accompanied drawings. In the following description, any discussion of the formation of a first layer on a second layer may include both a direct formation of the first layer on the second layer and an indirect formation of the first layer on the second layer with the interposition of a third layer therebetween. Further, although an example structure of a CMOS image sensor (CIS) is disclosed herein, example embodiments of the invention are not limited to the CISs, but also include all other type of image sensors that employ microlenses including, but not limited to, charge coupled devices (CCDs). For example, example embodiments of the invention include integrated circuit image sensors in which a photodiode is formed above a circuit area.

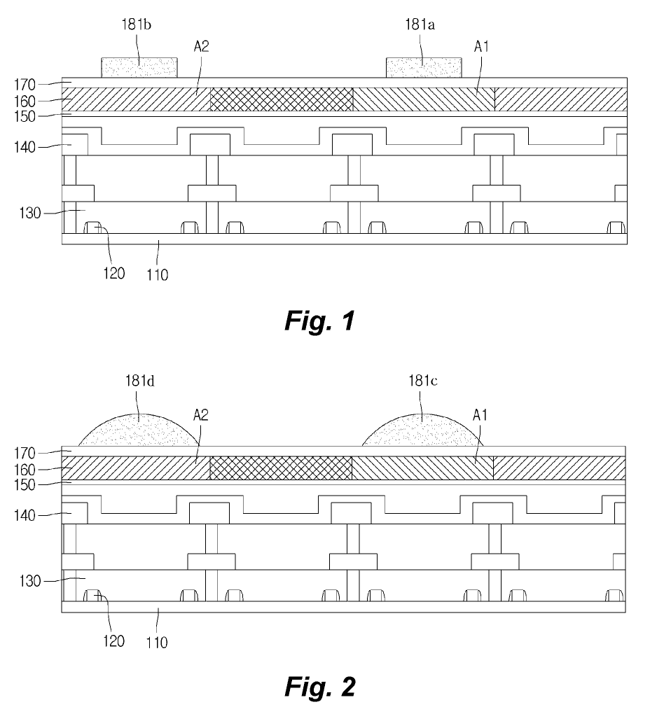

FIGS. 1 to 4 illustrate an example manufacturing process of an example image sensor. As disclosed in FIG. 1, an interlayer insulation layer 130 is formed on a pixel area formed on a substrate 110.

A photodiode (not shown) may be formed on the substrate 110. The photodiode may be formed to be horizontal to a transistor 120, or may be formed to be vertical to the transistor 120.

The interlayer insulation layer 130 may be formed of multiple layers. In detail, a first interlayer insulation layer may be formed, then a shield layer (not shown) may be formed, than a second interlayer insulation layer may be formed. The shield layer (not shown) may function to prevent light from being incident to a portion except a photodiode (not shown) area.

With continued reference to FIG. 1, a metal wiring 140 may be formed between the interlayer insulation layers 130. Then, a passivation layer 150 may be further formed on the interlayer insulation layer 130 to protect the device from moisture and scratches. The passivation layer 150 may be, for example, an oxide layer and/or a nitride layer, and may be a single layer or multiple layers.

Subsequently, a dyeable resist (not shown) covers the interlayer insulation layer 130. Then, a color filter layer 160 is formed through an exposure and developing process. The color filter layer may include filters capable of filtering light according to a predetermined wavelength. The filter may correspond to red, green, and blue wavelengths, for example. Then, a planarization layer (PL) 170 may be further formed on the color filter layer 160, to ensure, for example, a relatively flat surface for a formation of a focus distance control and lens layer. In some example embodiments, the color filter layer 160 may be omitted and color filtering may be accomplished instead by employing color microlenses, as described below.

Subsequently, first microlens patterns 181a and 181b may be formed on the interlayer insulation layer 130. The first microlens patterns 181a and 181b may be spaced apart from each other. That is, the first-microlens pattern 181a may be formed at a certain distance from the first microlens pattern 181b. For example, as disclosed in FIG. 1, the first microlens pattern 181a may be formed on a first pixel area A1, and the first microlens pattern 181b may be formed on a second pixel area A2. The second pixel area A2 may be positioned diagonal to the first pixel area A1.

With reference now to FIG. 2, the first microlens patterns 181a and 181b reflow, thereby forming first microlenses 181c and 181d. This reflow may be accomplished, for example, by placing the substrate 110 on a hot plate (not shown) set at a temperature of about 150° C. or more. This reflow results in the formation of the first microlenses 181c and 181d, each having a generally half-sphere shape. As disclosed in FIG. 2, the first microlens 181c may be formed on the first pixel area A1 and the first microlens 181d may be formed on the second pixel area A2. The second pixel area A2 may be positioned diagonal to the first pixel area A1. Alternatively, second pixel areas A2 may be positioned above, below, to the left of, and to the right of the first pixel area A1.

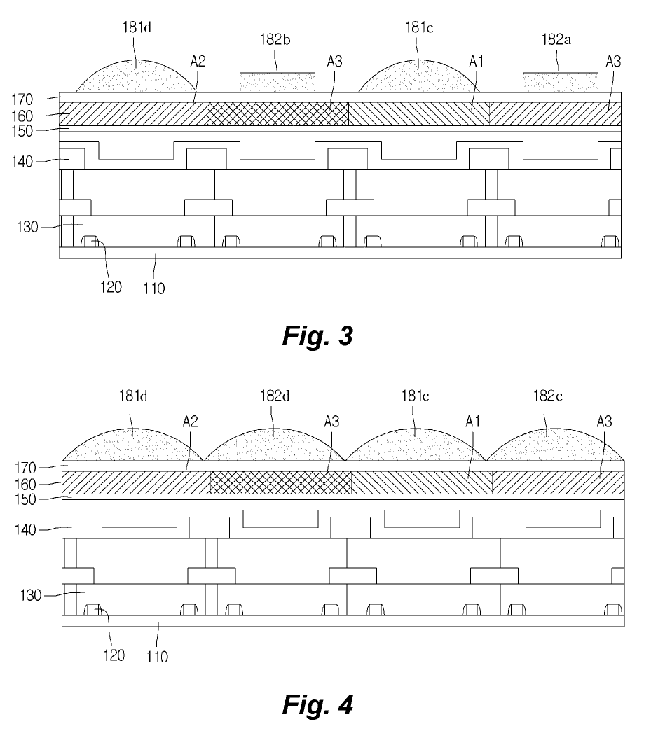

With reference now to FIGS. 3 and 4, second microlens patterns 182a and 182b may be formed on a third pixel area A3 beside the first and second pixel areas A1 and A2, as disclosed in FIG. 3. As disclosed in FIG. 4, the second microlens patterns 182a and 182b reflow, thereby forming second microlenses 182c and 182d. Thus, the second microlens 182c and 182d can be formed between the first microlenses 181c and 181d. In some example embodiments, the second microlenses 182c and 182d may be formed on the third pixel area A3 beside the first and second pixel areas A1 and A2, as disclosed in FIG. 4. In some example embodiments, the second microlenses 182c and 182d may be formed on third pixel area A3 positioned above, below, to the left of, and to the right of the first and second pixel areas A1 and A2.

In some example embodiments, the first microlenses 181c and 181d may be formed over a green color filter pixel area of the color filter layer 160 and the second microlenses 182c and 182d may be formed over a red color filter pixel area and a blue color filter pixel area, respectively, of the color filter layer 160. In other example embodiments, the first microlenses 181c and 181d may be formed over a red color filter pixel area and blue color filter pixel area, respectively, of the color filter layer 160 and the second microlenses 182c and 182d may be formed over a green color filter pixel area of the color filter layer 160.

In some example embodiments, the diameters of the first microlenses 181c and 181d may be different from the diameters of the second microlens 182c and 182d. For example, the diameters of the second microlens 182c and 182d may be larger than the diameters of the first microlens 181c and 181d.

When computing a microlens fill factor by comparing a pixel size and a microlens size of a single microlens process and a pixel size and a microlens size of a dual microlens process (the single microlens process forming a microlens through a one-step convention process and the dual microlens process forming a microlens through a two-steps process as disclosed herein), the fill factor of the dual microlens process is greater than the fill factor of the single microlens process. This increased fill factor reduces or prevents a gap between microlenses.

In addition, during the second microlens reflow, the reflow may be more extensive than the first microlens reflow, resulting in the second microlenses being sized differently from the first microlenses. In some alternative embodiments, the sizes of the first and second microlenses may be uniform.

In addition, some image sensors manufactured as disclosed herein have an increased sensitivity of about 2% for blue and red and about 10% for green. The reduction or elimination of gaps between the microlenses as disclosed herein results in relatively more light is transferred to photodiode, accordingly a sensitivity can be improved between about 5% and about 10% or more.

Although example embodiments of the present invention have been shown and described, changes might be made in these example embodiments. The scope of the invention is therefore defined in the following claims and their equivalents.

What is claimed is:

1. An image sensor comprising:
an interlayer insulation layer formed on a substrate of a pixel area;
a plurality of first microlenses spaced apart from each other on the interlayer insulation layer; and
a plurality of second microlenses formed beside the plurality of first microlenses, the plurality of second microlenses each having a diameter different from a diameter of each of the plurality of first microlenses.

2. The image sensor of claim 1, wherein the diameter of each second microlens is larger than the diameter of each first microlens.

3. The image sensor of claim 1, wherein each first microlens is formed on a first pixel area that is positioned diagonal to a second pixel area.

4. The image sensor of claim 3, wherein each second microlens is formed on a third pixel area positioned beside the first and second pixel areas.

5. The image sensor of claim 1, wherein the first microlenses are formed on a first pixel area and a second pixel area that is positioned above, below, to the left of, and to the right of the first pixel area.

6. The image sensor of claim 5, wherein the second microlens is formed on a third pixel area positioned beside the first and second pixel areas.

7. The image sensor of claim 1, further comprising a plurality of color filters corresponding to the first microlenses and the second microlens.

8. The image sensor of claim 7, wherein the first microlenses correspond to green color filters.

9. The image sensor of claim 7, wherein the second microlenses correspond to a red color filter and a blue color filter.

10. The image sensor of claim 7, wherein the first microlenses correspond to a red color filter and a blue color filter.

11. The image sensor of claim 7, wherein the second microlenses correspond to green color filters.

12. A method of manufacturing an image sensor, comprising:
forming an interlayer insulation layer on a substrate of a pixel area;
forming a plurality of first microlenses spaced apart from each other on the interlayer insulation layer; and
forming a plurality of second microlens beside the pluralities of first microlenses, the plurality of second microlenses each being formed to have a diameter different from a diameter of each of the plurality of first microlenses.

13. The method of claim 12, wherein the diameter of each second microlens is larger than the diameter of each of the plurality of the first microlenses.

14. The method of claim 12, wherein the plurality of first microlenses is formed on a first pixel area that is positioned diagonal to a second pixel area.

15. The method of claim 14, wherein each second microlens is formed on a third pixel area positioned beside the first and second pixel areas.

16. The method of claim 12, wherein the first microlens is formed on a first pixel area and a second pixel area that is positioned above, below, to the left of, and to the right of the first pixel area.

17. The method of claim 16, wherein the second microlenses are formed on a third pixel area positioned beside the first and second pixel areas.

18. The method of claim 17, wherein forming the second microlenses comprises:
forming a second microlens pattern on the third pixel area; and
forming the second microlenses through a reflow of the second microlens pattern.

19. The method of claim 16, wherein the second microlens is formed on a third pixel area positioned above, below, to the left of, and to the right of the first and second pixel areas.

20. The method of claim 12, wherein the first microlenses correspond to green color filters and the second microlenses correspond to a red color filter and a blue color filter.
